(19) United States
(12) Patent Application Publication
(10) Pub. No.: US 2019/0323657 A1
(43) Pub. Date: Oct. 24, 2019

(54) CONNECTION DEVICE AND ELECTRONIC DEVICE

(71) Applicant: SZ DJI TECHNOLOGY CO., LTD., Shenzhen (CN)

(72) Inventors: Tianhang MA, Shenzhen (CN); Xifeng ZHAO, Shenzhen (CN); Qiaoli ZHANG, Shenzhen (CN)

(21) Appl. No.: 16/503,023

(22) Filed: Jul. 3, 2019

Related U.S. Application Data
(63) Continuation of application No. PCT/CN2017/077689, filed on Mar. 22, 2017.

(30) Foreign Application Priority Data
Jan. 5, 2017 (CN) 201720013129.5

(51) Int. Cl. F16M 13/02; H01R 33/97; H05K 5/02

(52) U.S. Cl. CPC F16M 13/022; H01R 33/97; H05K 5/0017; H05K 5/0234; H05K 5/0247

(57) ABSTRACT

A connection device for connecting a first to-be-connected device and a second to-be-connected device includes a first connection member configured to connect with the first to-be-connected device. The first connection member includes a snap-fit groove. The connection device also includes a second connection member configured to connect with the second to-be-connected device. The second connection member includes a snap-fit hook configured to couple with the snap-fit groove to limit a relative motion between the first connection member and the second connection member.

### CROSS-REFERENCE TO RELATED APPLICATIONS

This application is a continuation application of International Application No. PCT/CN2017/077689, filed on Mar. 22, 2017, which claims priority to Chinese Patent Application No. 201720013129.5, filed on Jan. 5, 2017, the entire contents of both of which are incorporated herein by reference.

### TECHNICAL FIELD

The present disclosure relates to the technology field of electronic devices and, more particularly, to a connection device and an electronic device.

### BACKGROUND

When a remote control device is used to control a flying object, a user typically has to both look at a display of the remote control device to observe images captured by flying object and control the flying object. Therefore, a frame may be fixed to the remote control device such that the display may be connected to the frame. However, currently available displays and frames are not designed for convenient disassembling and mounting.

### SUMMARY

In accordance with an aspect of the present disclosure, there is provided a connection device for connecting a first to-be-connected device and a second to-be-connected device. The connection device includes a first connection member configured to connect with the first to-be-connected device. The first connection member includes a snap-fit groove. The connection device also includes a second connection member configured to connect with the second to-be-connected device. The second connection member includes a snap-fit hook configured to couple with the snap-fit groove to limit a relative motion between the first connection member and the second connection member.

Some of the additional aspects and advantages of the embodiments of the present disclosure will be explicitly described in the following descriptions, and some will become more obvious in the following descriptions. Alternatively, a person having ordinary skills in the art will understand the additional aspects and advantages by practicing the present disclosure.

### BRIEF DESCRIPTION OF THE DRAWINGS

To better describe the technical solutions of the various embodiments of the present disclosure, the accompanying drawings showing the various embodiments will be briefly described. As a person of ordinary skill in the art would appreciate, the drawings show only some embodiments of the present disclosure. Without departing from the scope of the present disclosure, those having ordinary skills in the art could derive other embodiments and drawings based on the disclosed drawings without inventive efforts.

FIG. 1 is a perspective view of an electronic device, according to an example embodiment.

FIG. 2 is another perspective view of the electronic device, according to an example embodiment.

FIG. 3 is a partial exploded view of the electronic device, according to an example embodiment.

FIG. 4 is a partial exploded view of the electronic device from another perspective, according to an example embodiment.

FIG. 5 is a perspective view of a connection device, according to an example embodiment.

FIG. 6 is a perspective view of the connection device from another perspective, according to an example embodiment.

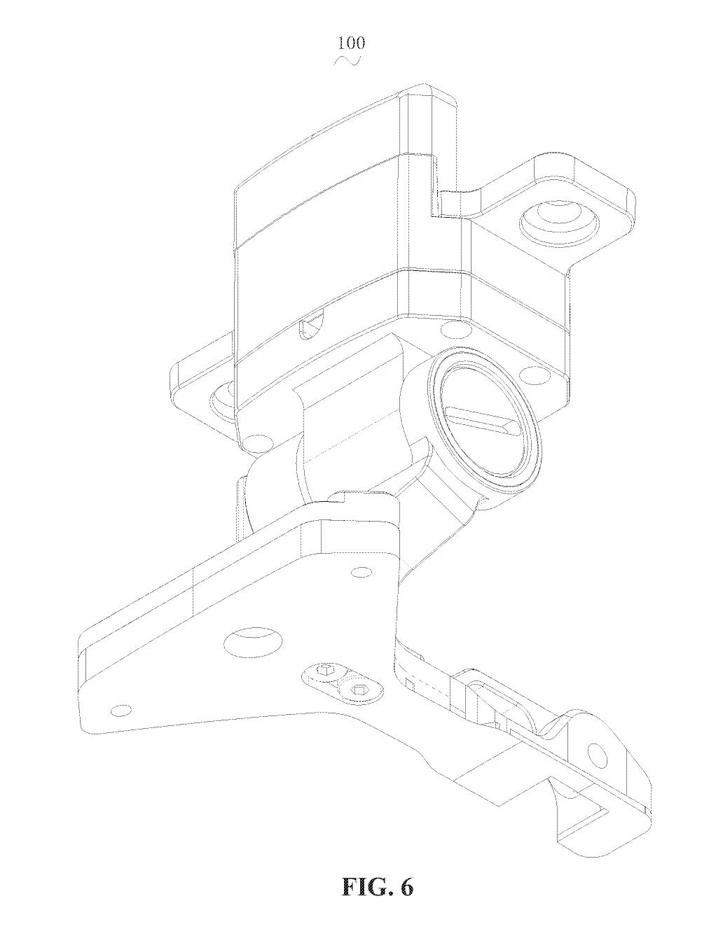

FIG. 7 is an exploded view of the connection device, according to an example embodiment.

FIG. 8 is an exploded view of the connection device from another perspective, according to an example embodiment.

FIG. 9 is a front view of the connection device, according to an example embodiment.

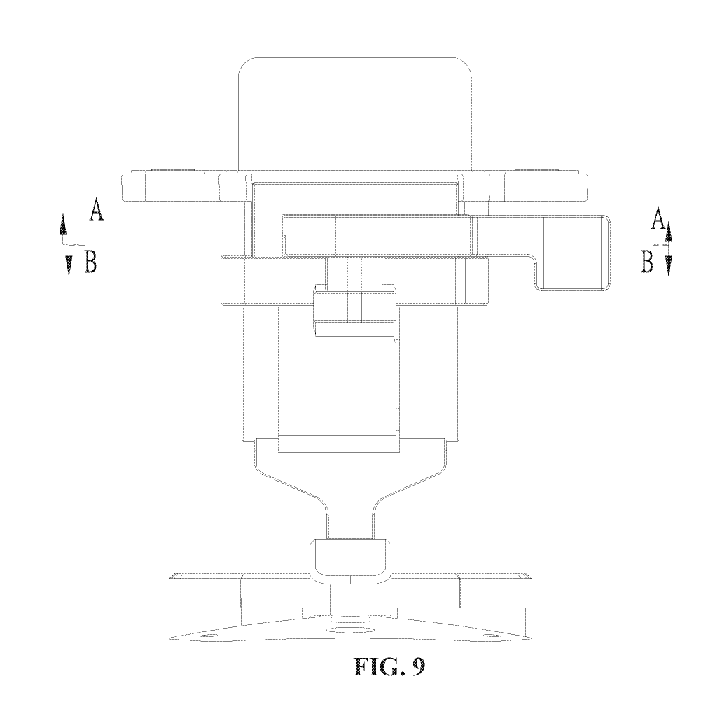

FIG. 10 is a cross-sectional view of the connection device along the A-A line shown in FIG. 9, which shows a snap-fit hook and a snap-fit groove in a tightly snap-fit state, according to an example embodiment.

FIG. 11 is a cross-sectional view of the connection device along the B-B line shown in FIG. 9, which shows a snap-fit hook and a snap-fit groove in a tightly snap-fit state, according to an example embodiment.

FIG. 12 is a cross-sectional view of the connection device along the A-A line shown in FIG. 9, which shows the snap-fit hook and the snap-fit groove in a released state, according to an example embodiment.

FIG. 13 is a cross-sectional view of the connection device along the B-B line shown in FIG. 9, which shows the snap-fit hook and the snap-fit groove in a released state, according to an example embodiment.

FIG. 14 is a cross-sectional view of a connection assembly of the connection device, according to an example embodiment.

FIG. 15 is a perspective view of an electronic device, according to an example embodiment.

FIG. 16 is an enlarged view of the XVI portion shown in FIG. 15, according to an example embodiment.

FIG. 17 is a perspective view of the connection device, according to an example embodiment.

FIG. 18 shows a process of coupling the snap-fit hook and the snap-fit groove, according to an example embodiment.

FIG. 19 is an enlarged view of the XIX portion shown in FIG. 18, according to an example embodiment.

### DETAILED DESCRIPTION OF THE EMBODIMENTS

The embodiments of the present disclosure will be described below. Examples of the embodiments are shown in the accompanying drawings, in which the same or similar umbers refer to the same or similar elements unless otherwise specified. It will be appreciated that the described embodiments shown in the drawings are illustrative, are only described to explain the present disclosure, and cannot be interpreted as being limiting the scope of the present disclosure.

It should be understood that in the present disclosure, terms such as “first” and “second,” etc., are only used for the purpose of descriptions, and should not be interpreted as indicating or implying the relative importance or implicitly indicate the quantity of the modified technical feature. Therefore, a feature modified by the term “first” or “second” may include, explicitly or implicitly, one or more such features. The term “multiple” means two or more than two, unless otherwise defined.

As used herein, unless there is express definition or limitation, the term “mount,” “couple,” or “connect” should be construed broadly. For example, they may include fixed connection, detachable connection, or integral connection. They may include mechanical connection, electrical connection, or communicative connection. They may include direct connection or connection through an intermediate medium. They may include connection between two elements or an interactive relationship between two elements. A person having ordinary skills in the art can interpret the meaning of the terms in the present disclosure based on specific context.

The present disclosure provides various different embodiments or examples for realizing the different structures of the present disclosure. To simplify the descriptions, next, the components and configurations of specific examples will be described. These descriptions are only for illustrative purposes, and do not limit the scope of the present disclosure. In addition, reference numbers and/or reference alphabets may be repeatedly used in different examples. Such repetition is for the purpose of simplification and clarity, and does not necessarily imply any relationship between the various embodiments and/or configurations. Moreover, the present disclosure provides examples of the specific processes and materials. A person having ordinary skills in the art can appreciate that other processes and/or other materials may also be used.

In addition, the singular forms “a,” “an,” and “the” are intended to include the plural forms as well, unless the context indicates otherwise. And, the terms “comprise,” “comprising,” “include,” and the like specify the presence of stated features, steps, operations, elements, and/or components but do not preclude the presence or addition of one or more other features, steps, operations, elements, components, and/or groups. The term “and/or” used herein includes any suitable combination of one or more related items listed. For example, A and/or B can mean A only, A and B, and B only. The symbol “/” means “or” between the related items separated by the symbol. The phrase “at least one of” A, B, or C encompasses all combinations of A, B, and C, such as A only, B only, C only, A and B, B and C, A and C, and A, B, and C. In this regard, A and/or B can mean at least one of A or B.

Further, when an embodiment illustrated in a drawing shows a single element, it is understood that the embodiment may include a plurality of such elements. Likewise, when an embodiment illustrated in a drawing shows a plurality of such elements, it is understood that the embodiment may include only one such element. The number of elements illustrated in the drawing is for illustration purposes only, and should not be construed as limiting the scope of the embodiment. Moreover, unless otherwise noted, the embodiments shown in the drawings are not mutually exclusive, and they may be combined in any suitable manner. For example, elements shown in one embodiment but not another embodiment may nevertheless be included in the other embodiment.

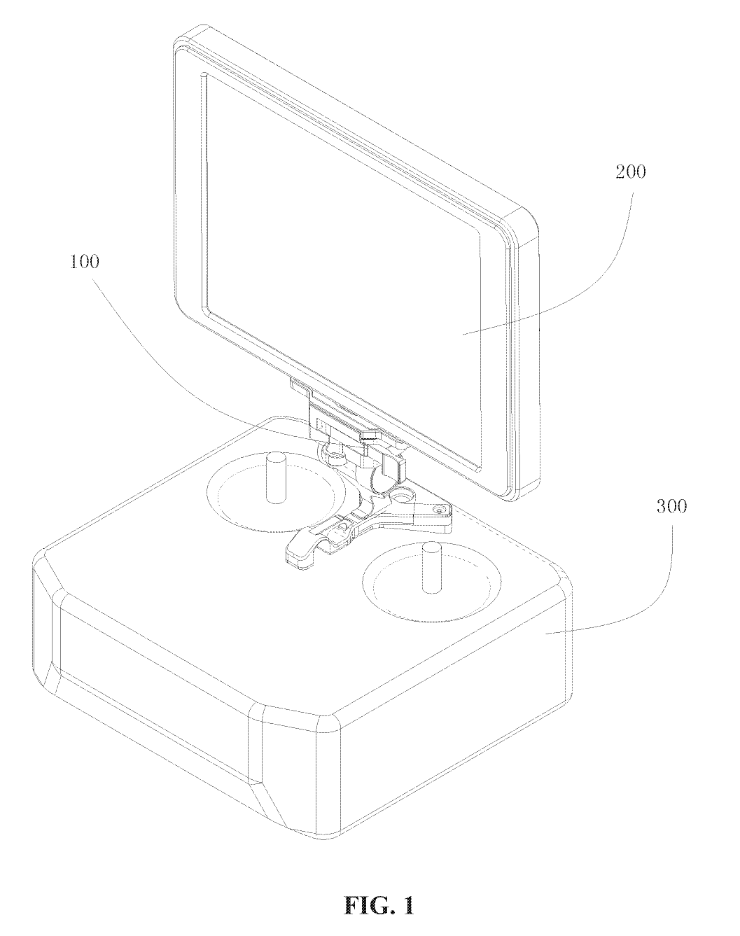

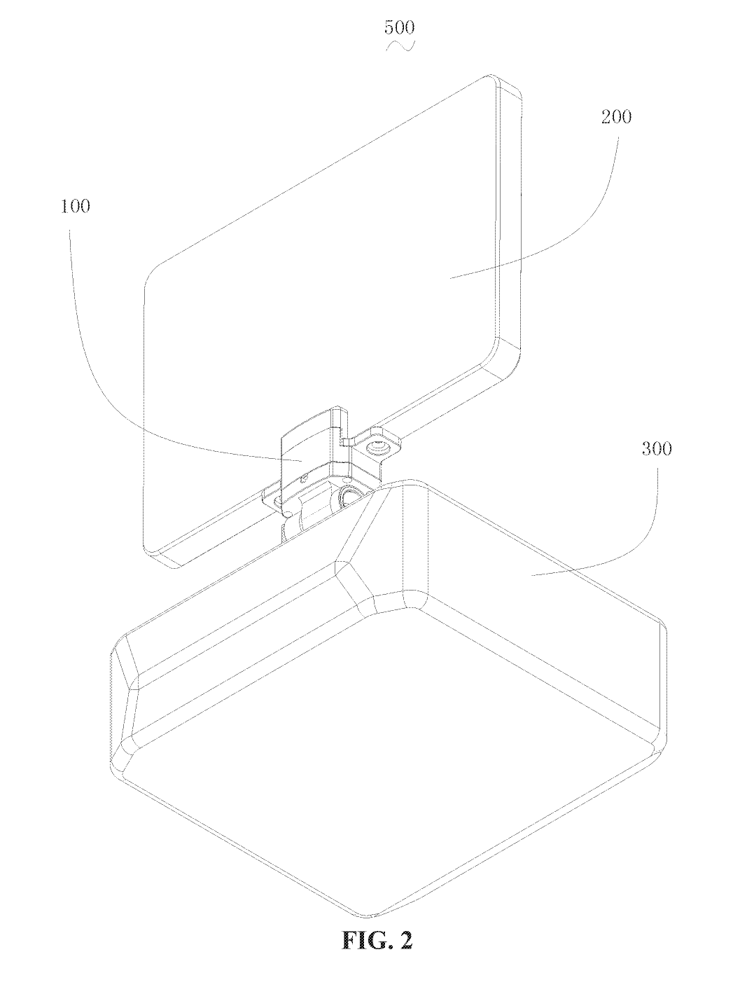

Referring to FIG. 1 and FIG. 2, the present disclosure provides a connection device 100 configured to connect a first to-be-connected device 200 and a second to-be-connected device 300. The first to-be-connected device 200 may be a device having a display function, such as a display, a cell phone, or a tablet. The first to-be-connected device 200 may also be other functional devices, such as a camcorder, a camera, etc. The second to-be-connected device 300 may be a remote control device, a helmet, etc. When the first to-be-connected device 200 is connected with the second to-be-connected device 300 through the connecting device 100 to form a remote control device having a display, the remote control device having a display may be configured to control unmanned aerial vehicles, unmanned cars, unmanned boats, robots, or other electronic devices that need to be remotely controlled.

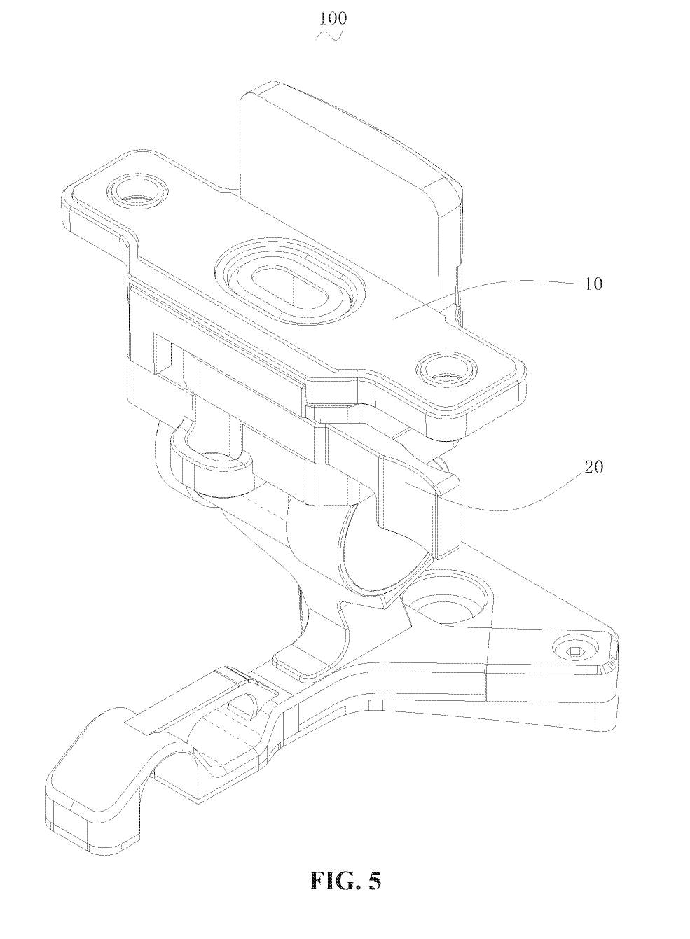

In some embodiments, referring to FIG. 5, the connection device 100 may include a first connection member 10 and a second connection member 20. The first connection member 10 may be configured to connect with the first to-be-connected device 200, and the second connection member 20 may be configured to connect with the second to-be-connected device 300. In the following descriptions of the embodiments, a display device is used as an example of the first to-be-connected device 200, and a remote control device is used as an example of the second to-be-connected device 300.

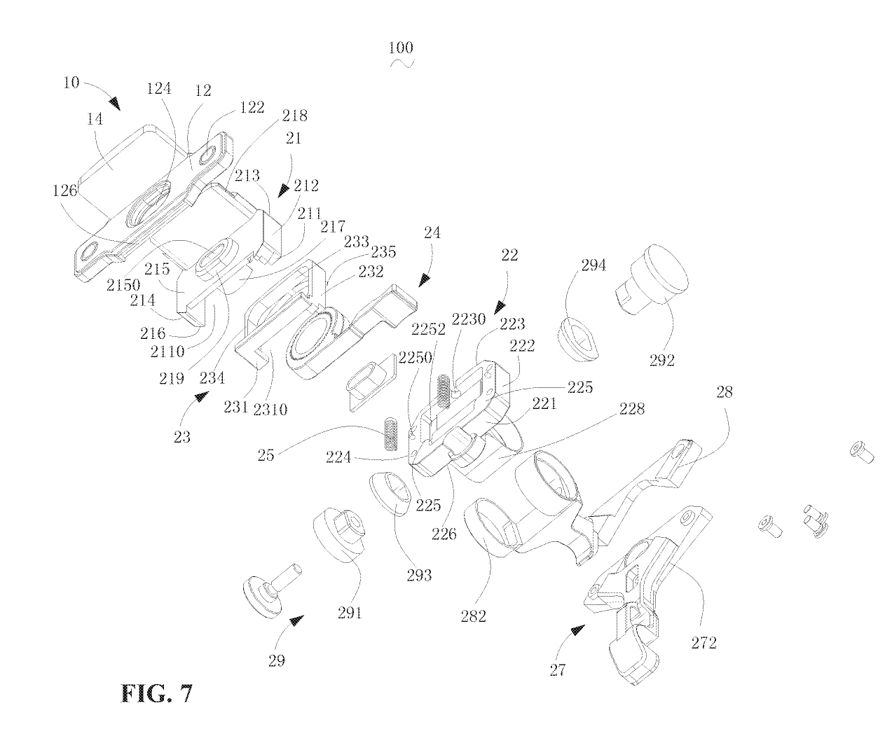

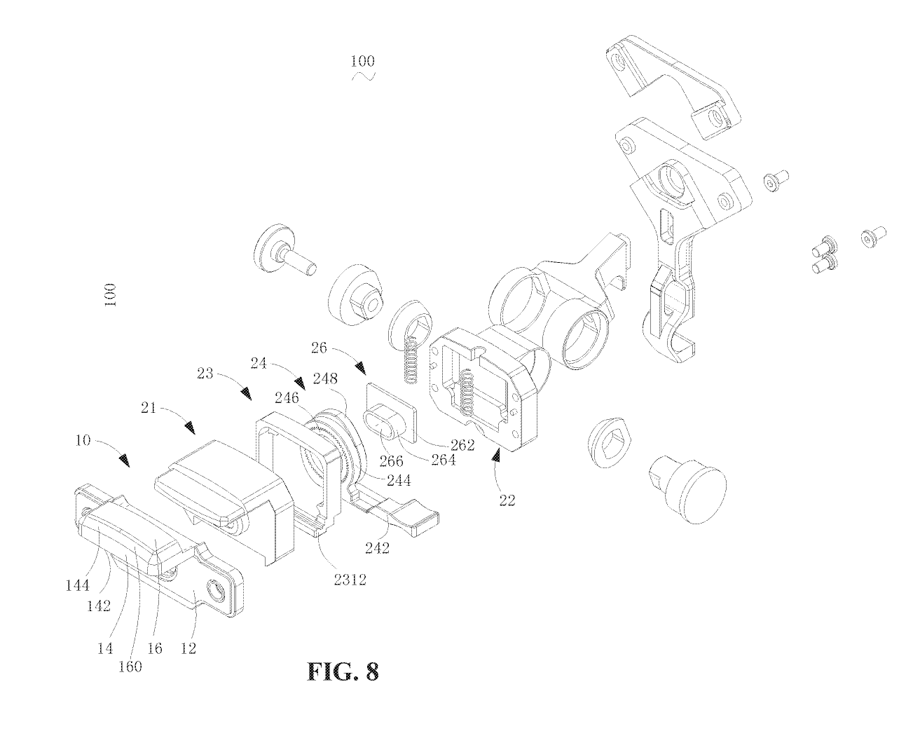

Referring to FIG. 5, FIG. 7, and FIG. 8, the first connection member 10 may include a base plate 12, a side plate 14 extending from a side of the base plate 12, and a position limiting member 16 provided on the base plate 12.

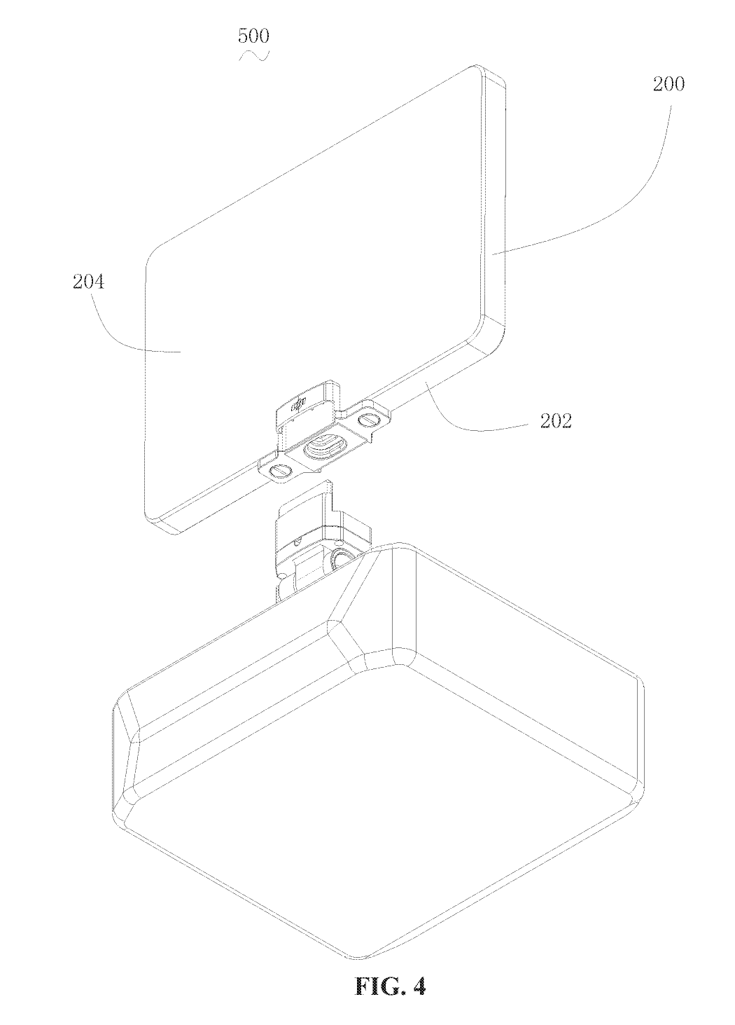

Referring to FIG. 4, the base plate 12 may be connected with (e.g., fixed on) the first to-be-connected device 200. In some embodiments, two ends of the base plate 12 may be respectively provided with threaded holes 122. A middle location of the base plate 12 may be provided with a first wire routing hole 124. A snap-fit groove 126 may be provided at a side of the base plate 12 opposing the side plate 14. Two mounting holes (not shown) may be provided at a bottom surface 202 of the first to-be-connected device 200 corresponding to the threaded holes 122. Two screws (not shown) may penetrate through the threaded holes 122 and screw into the mounting holes of the first to-be-connected device 200, thereby fixing the base plate 12 onto the first to-be-connected device 200. At this state, the side plate 14 is located at a side where a back surface 204 of the first to-be-connected device 200 is located. The side plate 14 may abut against the back surface 204 and block the first to-be-connected device 200 from flipping and separating from the second to-be-connected device 300. In some embodiments, the base plate 12 may be fixed onto the first to-be-connected device 200 through any one or any combination of the following connection methods: threaded connection, snap-fitting, gluing, and welding.

In some embodiments, the side plate 14 may include a front surface 142 and an opposing back surface 144. The front surface 142 may be disposed closer to the first to-be-connected device 200 than the back surface 144. In some embodiments, the first to-be-connected device 200 may abut against the front surface 142. In other embodiments, the first to-be-connected device 200 may not contact the front surface 142. The position limiting member 16 may extend from the back surface 144, and may form a position limiting groove 160 with the back surface 144.

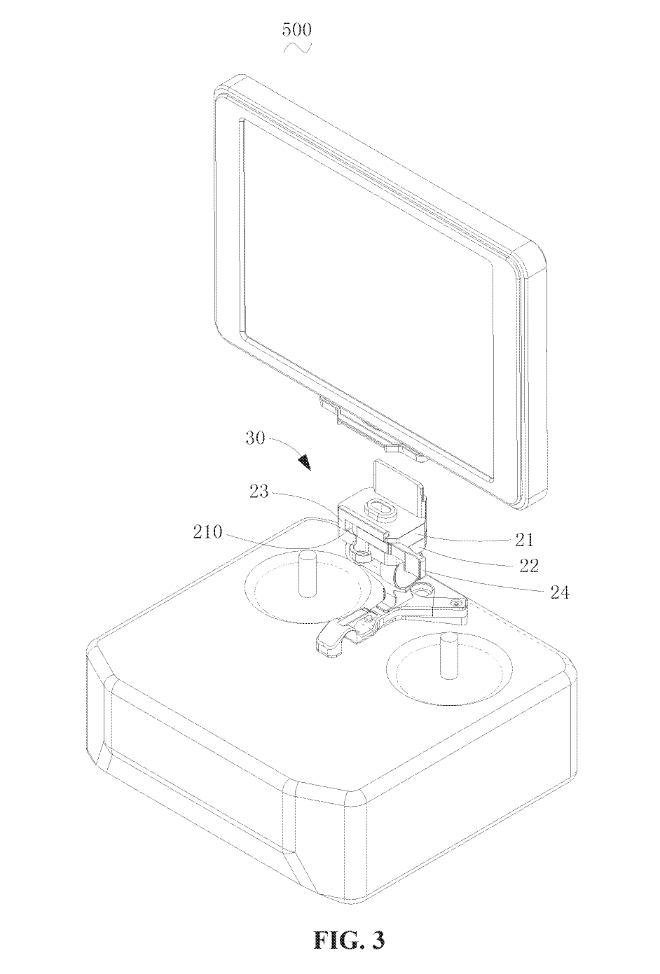

Referring to FIG. 3, the second connection member 20 may include a transfer member 21, a load-bearing member 22, a movable member 23, and a transmission assembly 24. The transfer member 21 and the load-bearing member 22 may be assembled to form a receiving space 210. The movable member 23 may be at least partially received in the receiving space 210. The transmission assembly 24 may be at least partially received in the receiving space 210.

Referring to FIG. 7 and FIG. 8, the transfer member 21 may have a substantially cuboidal shape with two sides opened. The transfer member 21 may include a first side wall 211, a second side wall 212, a third side wall 213, and a fourth side wall 214 connected in sequence. The first side wall 211 may include an opening 2110. The second side wall 212, the third side wall 213, and the fourth side wall 214 may all be closed side walls. The transfer member 21 may include a top wall 215 and a bottom wall 216 that are connected with the first side wall 211, the second side wall 212, the third side wall 213, and the fourth side wall 214. The bottom wall 216 may be open, and may be provided with a positioning hole (not shown). The top wall 215 may be provided with a second wire routing hole 2150.

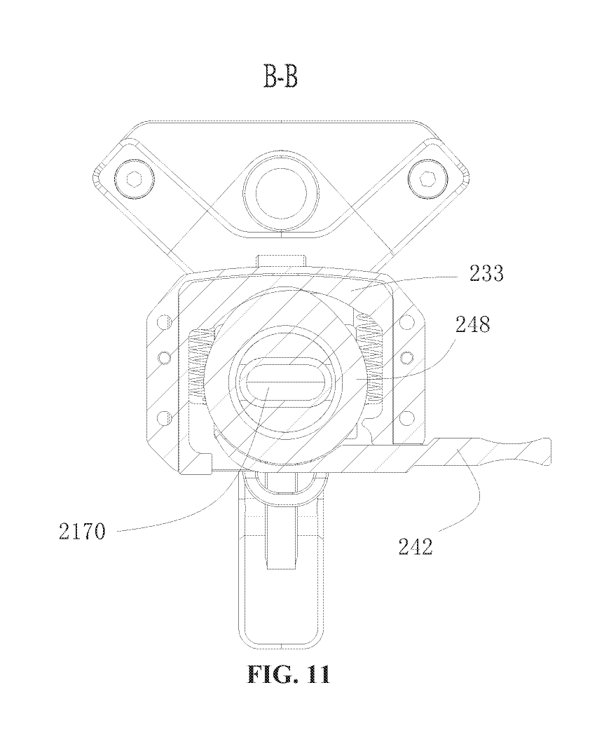

In some embodiments, the transfer member 21 may include a positioning shaft 217 and a blocking plate 218. The positioning shaft 217 may extend from the top wall 215 to the bottom wall 216. The positioning shaft 217 may be provided with a third wire routing hole 2170 (shown in FIG. 11). The first wire routing hole 124, the second wire routing hole 2150, and the third wire routing hole 2170 may be aligned. The blocking plate 218 may extend from a portion of the top wall 215 that is close to the third side wall 213 in a direction away from the positioning shaft 217. When the first to-be-connected device 200 is connected with the second to-be-connected device 300 through the connection device 100, the blocking plate 218 may be partially or completely received in the position limiting groove 160.

In some embodiments, the side plate 14 and the position limiting member 16 of the first connection member 10 may be omitted. Correspondingly, the blocking plate 218 of the transfer member 21 may be omitted. In some embodiments, the base plate 12 of the first connection member 10 may be fixed to the first to-be-connected device 200 through other methods, such as screws. The transfer member 21 may be connected with the first connection member 10 through the positioning shaft 217.

In some embodiments, the load-bearing member 22 may have a substantially cuboidal structure with one side opened. The load-bearing member 22 may include a first side wall 221, a second side wall 222, a third side wall 223, and a fourth side wall 224 connected in sequence. The third side wall 223 may include a wire receiving hole 2230. The load-bearing member 22 may include a top wall 225 and a bottom wall 226 that are connected with the first side wall 221, the second side wall 222, the third side wall 223, and the fourth side wall 224. The top wall 225 may be provided with a positioning column 2250 and a receiving groove 2252. The load-bearing member 22 may be assembled with the transfer member 21 through any one or any combination of the following connection methods: threaded connection, snap-fitting, gluing, and welding. In some embodiments, the bottom wall 216 of the transfer member 21 may be loaded on and supported by the top wall 225 of the load-bearing member 22. The positioning column 2250 may snap-fit in the position limiting hole on the bottom wall 216. The first side wall 221, the second side wall 222, the third side wall 223, and the fourth side wall 224 of the load-bearing member 22 may correspond to the firs side wall 211, the second side wall 212, the third side wall 213, and the fourth side wall 214 of the transfer member 21, respectively.

In some embodiments, the movable member 23 may have a substantially rectangular frame shape. The movable member 23 may be loaded on and supported by the load-bearing member 22. In some embodiments, the movable member 23 may include a first side wall 231, a second side wall 232, a third side wall 233, and a fourth side wall 234 connected in sequence around the positioning shaft 217. The first side wall 231 may include a through hole 2310 corresponding to the opening 2110. The first side wall 231, the second side wall 232, and the third side wall 233 may be received in the receiving space 210. The fourth side wall 234 may extend from the opening 2110. In some embodiments, the first side wall 231, the second side wall 232, and the third side wall 233 may be loaded on and supported by the top wall 225 of the load-bearing member 22. The first side wall 231, the second side wall 232, the third side wall 233, and the fourth side wall 234 of the movable member 23 may correspond to and be connected with the first side wall 221, the second side wall 222, the third side wall 223, and the fourth side wall 224 of the load-bearing member 22, respectively. The movable member 23 may include a snap-fit hook 2312 located at a top end of the first side wall 231 and exposed from the opening 2110. The movable member 23 may be configured to move in the receiving space 210 such that the snap-fit hook 2312 may tightly snap-fit with the snap-fit groove 126 or to release from the snap-fit groove 126 to limit the relative motion between the first connection member 10 and the second connection member 20.

In some embodiments, the transmission assembly 24 may be loaded on and supported by the top wall 225 of the load-bearing member 22, and may sleeve-fit onto the positioning shaft 217. The transmission assembly 24 may be received in the movable member 23. The transmission assembly 24 may include a driving rod 242, a first transmission member 244, a second transmission member 246, and a cam 248. The driving rod 242 may extend from the opening 2110. The first transmission member 244 may be fixedly connected with the driving rod 242. The second transmission member 246 may couple with the first transmission member 244. The cam 248 may be fixedly connected with the second transmission member 246. In some embodiments, the first transmission member 244 may be include first gear, the second transmission member 246 may include a second gear. The coupling between the second transmission member 246 and the first transmission member 244 may include teeth meshing. The first gear may include an internal gear. The driving rod 242 may extend from an outer circular circumferential surface of the first gear. For example, the driving rod 242 may extend in a tangent direction of the outer circular circumferential surface of the first gear. The second gear may include an external gear. The second gear may extend from an end surface of the cam 248. The second gear may be integrally formed with the cam 248. Alternatively, the second gear and the cam may be separately formed and may be assembled together through any one or any combination of the following connection methods: welding, threaded connection, snap-fitting, gluing, etc.

In some embodiments, the first transmission member 244 and the cam 248 may be separately provided. When the manufacturing precision is not sufficiently high, the relative location relationship between the first transmission member 244 and the cam 248 may be adjusted, such that the abutting force exerted by the cam 248 on the movable member 23 when they are adjusted to tightly lock reaches a predetermined force. In the meantime, one may adjust the relative location relationship between the first transmission member 244 and the cam 248, such that the transmission assembly 24 can be suitable for components of different structures or different scenes. Such configurations increase the compatibility and operational flexibility of the transmission assembly 24.

In some embodiments, the first gear may include an external gear. The driving rod 242 may extend from an outer circular circumferential surface of the first gear. The second gear may include an internal gear. The second gear may extend from an end surface of the cam 248.

In some embodiments, the driving rod 242, the first transmission member 244, the second transmission member 246, and the cam 248 may be an integral structure, and may sleeve-fit onto the positioning shaft 217 of the transfer member 21. Operating the driving rod 242 may cause the cam 248 to rotate relative to the positioning shaft 217.

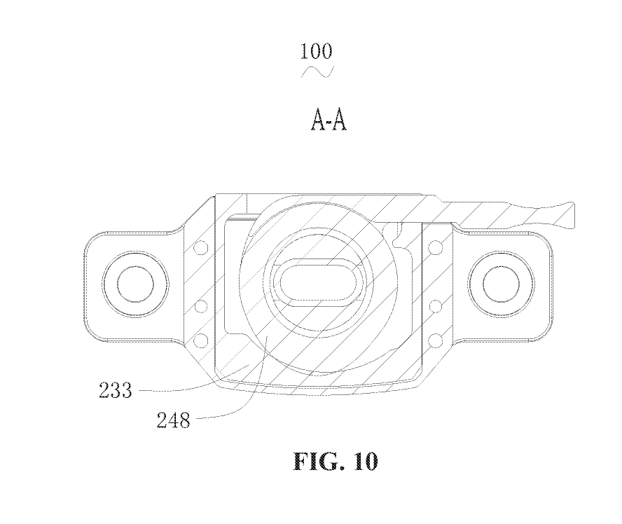

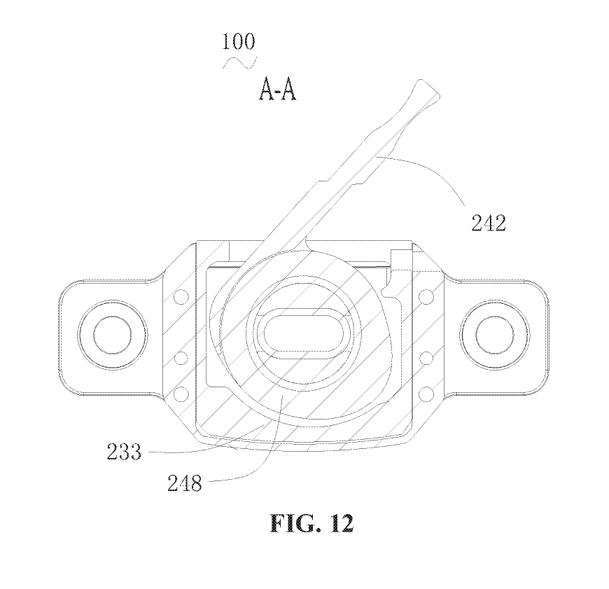

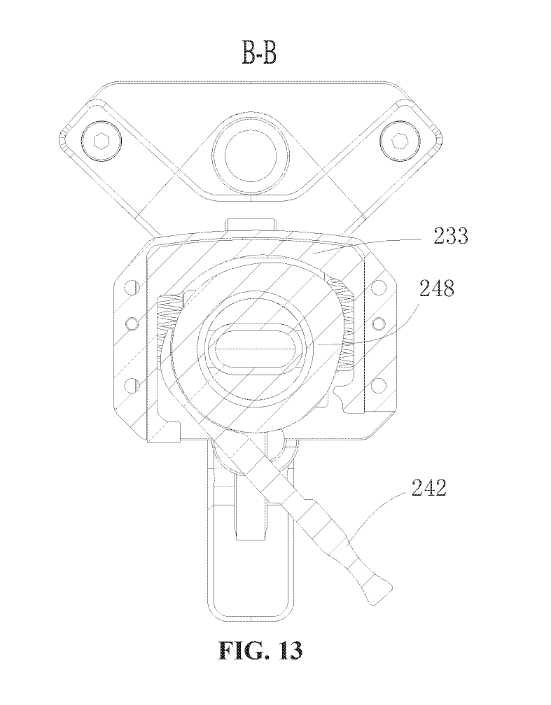

Referring to FIG. 3-FIG. 4, and FIG. 10-FIG. 13, during operation, the load-bearing member may be fixed onto the second to-be-connected device 300 through any one or any combination of the following connection methods: welding, threaded connection, snap-fitting, or gluing, such that the second connection member 20 is fixed onto the second to-be-connected device 300. Then the first connection member 10 may be fixed onto the first to-be-connected device 200 through any one or any combination of the above connection methods. The base plate 12 of the first connection member 10 connected with the first to-be-connected device 200 may be loaded onto the top wall 215 of the transfer member 21. The first wire routing hole 124, the second wire routing hole 2150, and the third wire routing hole 2170 may be aligned. The blocking plate 218 may be partially received in the position limiting groove 160 to block the first to-be-connected device 300 from flipping and separating from the second to-be-connected device 300, and to tightly couple the snap-fit hook 2312 with the snap-fit groove 126 to release the snap-fitting coupling. As shown in FIG. 10 and FIG. 11, in a state in which the snap-fit hook 2312 and the snap-fit groove 126 are tightly snap-fit with one another, the top end of the cam 248 may abut against the third side wall 233 of the movable member 23, such that the movable member 23 may move close to the third side wall 233 to the maximum extent. Correspondingly, the snap-fit hook 2312 may move close to the third side wall 233 to the maximum extent to completely occlude with the snap-fit groove 126 to achieve the tight snap-fit coupling. As shown in FIG. 12 and FIG. 13, in a state in which the coupling between the snap-fit hook 2312 and the snap-fit groove 126 is released, compared to the state in which the snap-fit hook 2312 and the snap-fit groove 126 are tightly snap-fit, the driving rod 242 may be pushed in a clockwise direction to rotate (viewed from the overlook perspective in FIG. 13), the first transmission member 244 may rotate clockwise along with the driving rod 242, thereby causing the cam 248 to rotate clockwise. The end of the cam 248 may release the third side wall 233 of the movable member 23. When an external force is applied on the first side wall 231 of the movable member 23, the movable member 23 may move in a direction away from the third side wall 223 of the load-bearing member 22. Correspondingly, under the external force, an area of the tight snap-fitting between the snap-fit hook 2312 and the snap-fit groove 126 may gradually reduce until the released state is reached when the snap-fit hook 2312 is completely separated from the snap-fit groove 126. When the snap-fit hook 2312 and the snap-fit groove 126 are in a tightly snap-fit state, the first to-be-connected device 200 may be fixedly connected with the second to-be-connected device 300. When the snap-fit hook 2312 and the snap-fit groove 126 are in a released state, the first to-be-connected device 200 may be quickly detached from the second to-be-connected device 300, thereby achieving a fast disassembling effect, which is quick and convenient. In some embodiments, the first to-be-connected device 200 and the second to-be-connected device 300 may be electrically connected through a wire. The wire may penetrate through the wire receiving hole 2230, the first wire routing hole 124, the second wire routing hole 2150, and the third wire routing hole 2170. The first wire routing hole 124, the second wire routing hole 2150, and the third wire routing hole 2170 may each have a running-track shape, which may function to restrain the wires, such that the internal structure of the connection device 100 becomes more compact. In some embodiments, the disposition locations of the first wire routing hole 124, the second wire routing hole 2150, and the third wire routing hole 2170 may not be limited to the above configurations. In some embodiments, the base plate 12 may include the first wire routing hole 124, the top wall 215 may be provided with a boss 219 (shown in FIG. 8) having the second wire routing hole 2150. The positioning shaft 217 may be provided with the third wire routing hole 2170. The boss 219 may couple with the first wire routing hole 124. The first wire routing hole 124, the second wire routing hole 2150, and the third wire routing hole 2170 may be aligned. In some embodiments, the base plate 12 may be provided with a boss having the first wire routing hole 124, the top wall 215 may be provided with the second wire routing hole 2150, and the positioning shaft 217 may be provided with the third wire routing hole 2170. The boss 219 may couple with the second wire routing hole 2150. The first wire routing hole 124, the second wire routing hole 2150, and the third wire routing hole 2170 may be aligned.

In some embodiments, the second connection member 20 may include two return springs 25 configured to be received in the receiving space 210 and the receiving groove 2252. Correspondingly, the movable member 23 may include two return columns 235 corresponding to the two return springs 25. The two return columns 235 may extend from a bottom surface of the third side wall 233 of the movable member 23 that is close to the load-bearing member 22. The two return columns 235 may be received in the receiving groove 2252. An end of each of the return springs 25 may abut against a corresponding return column 235, and another end of each of the return springs 25 may abut against an inner wall of the receiving groove 2252. At this state, regardless of whether the snap-fit hook 2312. and the snap-fit groove 126 are in a released state or a tightly snap-fit state, the return springs 25 may apply a force on the return columns 235. When the snap-fit hook 2312 and the snap-fit groove 126 are in a released state, the force may restrict the shaking or moving of the movable 23 in the receiving space 210, which may improve the user experience. In some embodiments, the two return columns 235 may be replaced by a plate-shaped structure.

Referring to FIG. 7, in some embodiments, the second connection member 20 may include a wire routing member 26 received in the receiving space 210. The wire routing member 26 may include a wire pressing plate 262 and a wiring boss 264 extending from the wire pressing plate 262 toward the transfer member 21. The wire routing member 26 may be provided with a fourth wire routing hole 266 penetrating through the wiring boss 264 and the wire pressing plate 262. The wiring boss 264 may extend into the third wire routing hole 2170. The wire pressing plate 262 may be configured to press a wire for electrically connecting the first to-be-connected device 200 and the second to-be-connected device 300. The wiring boss 264 may also function to restrain the wires. The configuration of the wire routing member 26 may further improve the function of restraining wires, such that the internal structure of the connection device 100 becomes more compact.

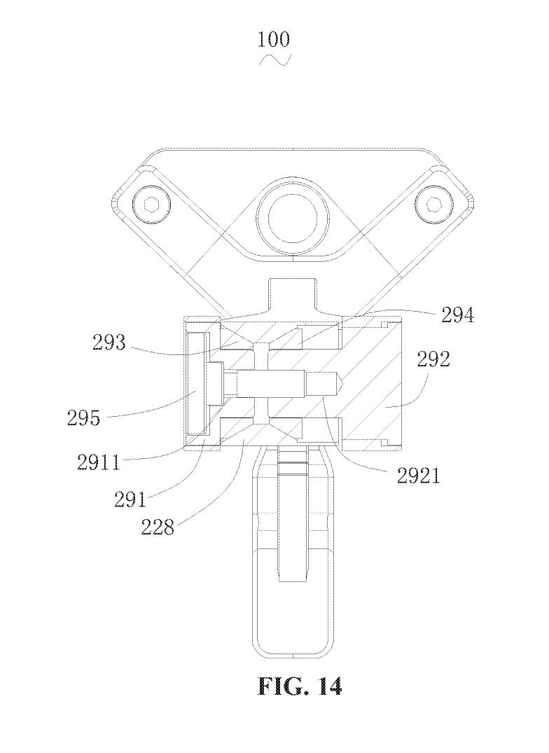

Referring to FIG. 8 and FIG. 14, in some embodiments, the load-bearing member 22 may include a rotation arm 228. The second connection member 20 may include a base 27, a supporting arm 28, and a connection assembly 29.

The base 27 may be configured to connect the second connection member with the second to-be-connected device 300. In some embodiments, the base 27 may include three supporting legs 272 distributed in a substantial Y shape. Each of the supporting legs 272 may be connected with the second to-be-connected device 300. The connection method for connecting each of the supporting legs 272 and the second to-be-connected device 300 may be any one of or any combination of the following methods: threaded connection, snap-fitting, gluing, or welding. For example, the three supporting legs 272 may be connected with the second to-be-connected device 300 through threaded connections. In some embodiments, one of the supporting legs 272 may be connected with the second to-be-connected device 300 through snap-fitting, and the other two supporting legs 272 may be connected with the second to-be-connected device 300 through threaded connections. The shape of the base 27 may be other suitable shape, which is not limited to the above descriptions.

In some embodiments, the supporting arm 28 may be fixedly connected with the base 27. The connection method for connecting the supporting arm 28 and the base 27 may be any one or any combination of the following methods: threaded connection, snap-fitting, gluing, or welding. An end of the supporting arm 28 may be inserted into the base 27, and another end of the supporting arm 28 may be fixedly provided with two shaft sleeves 282 that are opposingly and co-axially disposed. External walls of the shaft sleeves 282 may be fixedly connected with the supporting arm 28.

In some embodiments, the connection assembly 29 may be provide at an end of the supporting arm 28 away from the base 27. The rotation arm 228 may be sleeve-fit onto the connection assembly 29 and may be configured to rotate to a target location around the connection assembly 29. A pre-tightening force may exist between the rotation arm 228 and the connection assembly 29, which may maintain the rotation arras 228 at the target location. In some embodiments, the connection assembly 29 may include a first shaft 291, a second shaft 292, a first lining block 293, and a second lining block 294. The first shaft 291 may extend from a side of the supporting arm 28. The second shaft 292 may extend from another side of the supporting arm 28, and may be opposingly and separately disposed from the first shaft 291. In some embodiments, the first shaft 291 may extend into one of the shaft sleeves 282 from one side, and the second shaft 292 may extend into the other one of the shaft sleeves 282 from another side. The first shaft 291 and the second shaft 292 may be co-axially disposed and may form an adjustable gap therebetween. The first lining block 293 may be sleeve-fit onto the first shaft 291. The second lining block 294 may be sleeve-fit onto the second shaft 292. The rotation arm 228 may be sleeve-fit onto the first lining block 293 and the second lining block 294, and may be located between the first lining block 293 and the second lining block 294. The first lining block 293 and the second lining block 294 may be elastic components, such as rubber, washer, etc. The first lining block 293 and the second lining block 294 may push the rotation arm 228. When the rotation arm 228 rotates, friction may exist between the rotation arm 228 and the first lining block 293 and the second lining block 294 to provide the pre-tightening force. At this state, the rotation arm 228 may rotate to the target location around the connection assembly 29, and may remain at the target location under the pre-tightening force. As such, a user may adjust the first to-be-connected device 200 to a suitable angle for the convenience of observation or operation.

In some embodiments, the first shaft 291 may be provided with a mounting hole 2911, and the second shaft 292 may be provided with a threaded hole 2921. The connection assembly 29 may include an adjusting member 295. The adjusting member 295 may penetrate through the mounting hole 2911 and couple with the threaded hole 2921 to adjust the pre-tightening force. In some embodiments, the adjusting member 295 may be provided at a side of the first shaft 291, and may include external threads. The adjusting member 295 may couple with the threaded hole 2921 of the second shaft 292. Rotating the adjusting member 295 may change the coupling depth of the adjusting member 295 and the second shaft 292, i.e., may change the gap between the first shaft 291 and the second shaft 292. In other words, rotating the adjusting member 295 may change the pressure between the first lining block 293 and the second lining block 294 and the rotation arm 228, which further changes the pre-tightening force. When the weight of the first to-be-connected device 200 is relatively heavy, to maintain the rotation arm 228 at the target location, the adjusting member 295 may be suitably rotated to reduce the gap between the first shaft 291 and the second shaft 292, and to increase the friction force between the first lining block 293 and the second lining block 294 and the rotation arm 228, thereby increasing the pre-tightening force. Likewise, when the weight of the first to-be-connected device 200 is relatively light, to render the rotation arm 228 easy to rotate, the adjusting member 295 may be suitably rotated to increase the gap between the first shaft 291 and the second shaft 292, and to reduce the friction force between the first lining block 293 and the second lining block 294 and the rotation arm 228, thereby reducing the pre-tightening force.

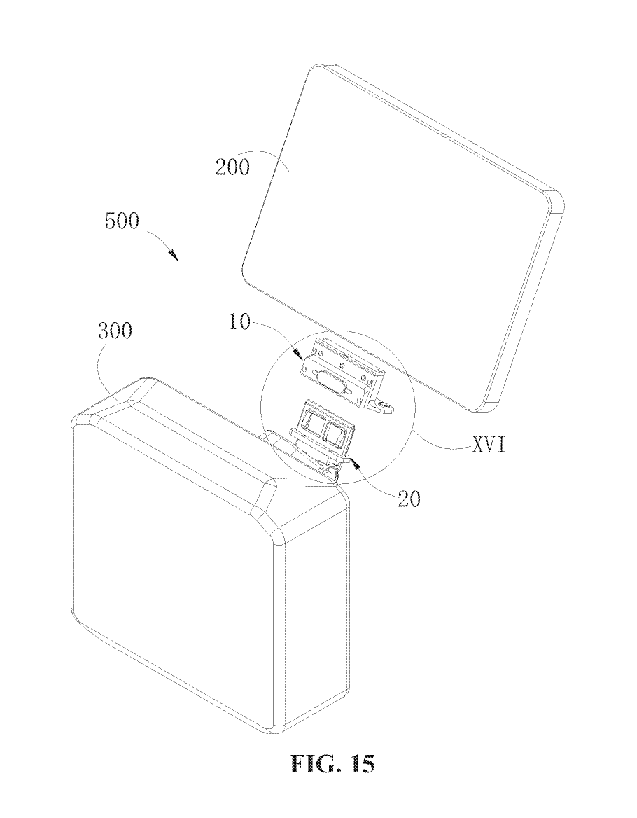

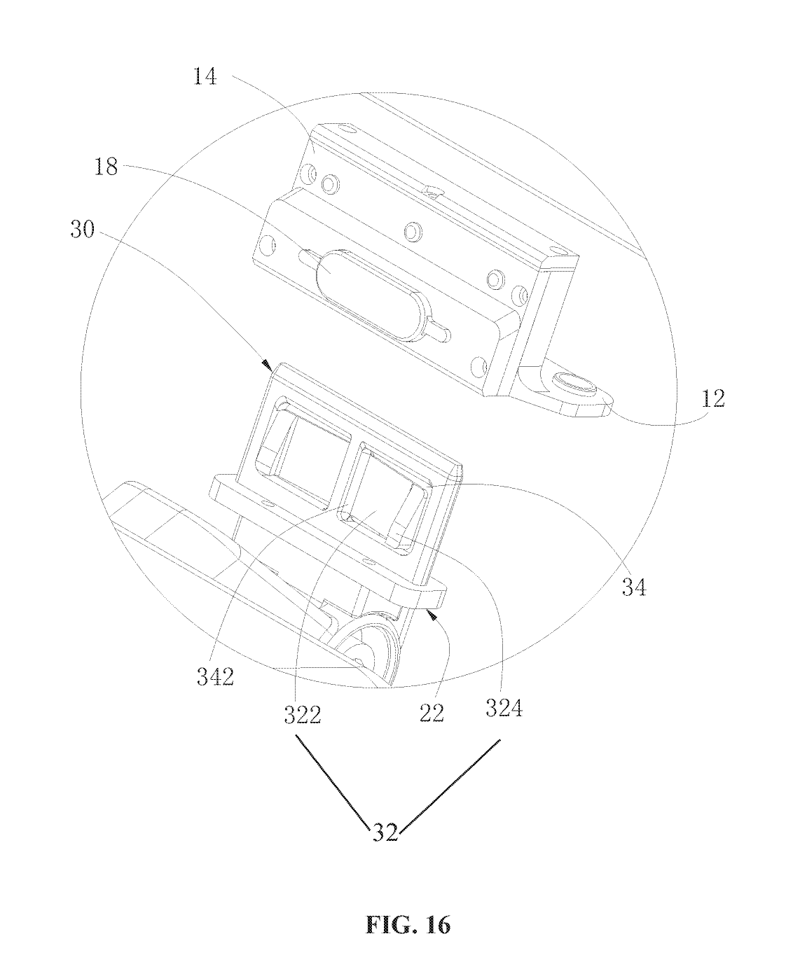

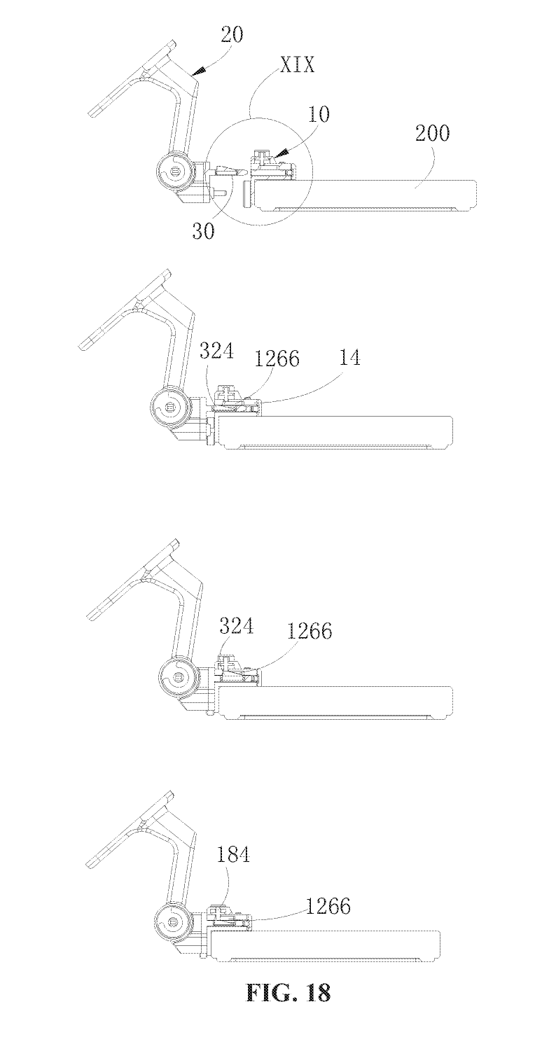

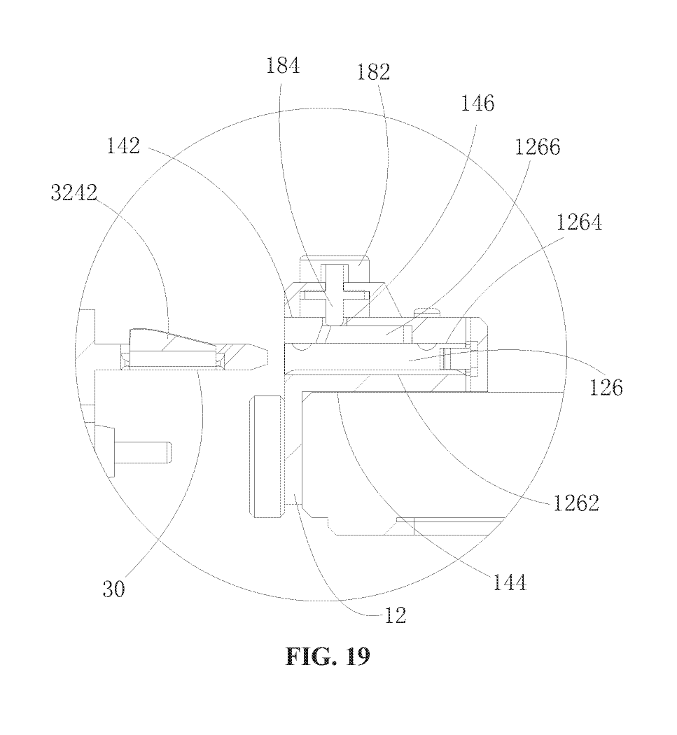

Referring to FIG. 15-FIG. 19, in some embodiments, the second connection member 20 may include a connecting insertion plate 30 extending from a top surface of the load-bearing member 22. A snap-fit hook 32 may be provided on the connecting insertion plate 30. The connecting insertion plate 30 may be inserted into the snap-fit groove 126 such that the snap-fit hook 32 may couple with the snap-fit groove 126. In some embodiments, the connecting insertion plate 30 may be provided with a snap-fitting hole 34 surrounded by a connection wall 342. The snap-fit hook 32 may include an elastic plate 322 extending from the connection wall 342 and a snap-fit block 324 provided on the elastic plate 322. The snap-fit block 324 may swing under an external force and may restore to a natural location when the external force is released. The snap-fit block 324 may include a snap-in segment 3242. The thickness of the snap-in segment 3242 may gradually reduce in a direction approaching the first connection member 10. As such, when the snap-fit block 324 is pushed into the snap-fit groove 126, the snap-in segment 3242 and the snap-fit groove 126 may quickly fix their locations, which makes it smoother to insert the connecting insertion plate 30 into the snap-fit groove 126.

In some embodiments, the snap-fit groove 126 may include a first wall 1262 and an opposing second wall 1264. The first wall 1262 may be disposed closer to the first to-be-connected device 200 than the second wall 1264. The snap-fit groove 126 may include a groove 1266 formed on the second wall 1264. The snap-fit block 324 may snap-into the groove 1266 such that the snap-fit hook 32 may couple with the snap-fit groove 126. In some embodiments, during the process the snap-fit block 324 extends into the snap-fit groove 126, the snap-in segment 3242 may contact the second wall 1264 and the elastic plate 322 may undergo an elastic deformation. When the snap-fit block 324 completely extends into the corresponding area of the groove 1266, the snap-fit block 324 may restore to its natural state under the elastic force of the elastic plate 322. The snap-fit block 324 may snap-into the groove 1266 and couple with the snap-fit groove 1266. At this state, the snap-fit block 324 may abut against an inner wall of the groove 1266. The snap-fit block 324 may not extend out of the groove 1266. As such, the first connection member 10 and the second connection member 20 may be fixedly connected.

In some embodiments, the snap-fit groove 126 may extend into the side plate 14. The side plate 14 may include a through hole 146 penetrating through the front surface 142 and connected with the groove 1266. The first connection member 10 may include a pressing member 18. The pressing member 18 may extend into the through hole 146, and may penetrate through the through hole 146 and extend into the groove 1266 to push the snap-fit block 324 to move out of the groove 1266. In some embodiments, the pressing member 18 may include a pressing cap 182 exposed at the front surface 142 and a pressing rod 184 partially extending into the through hole 146. Pressing the pressing cap 182 may cause the pressing rod 184 to penetrate through the through hole 146 and to push the snap-fit block 324 to move out of the groove 1266. The elastic plate 322 may undergo an elastic deformation. At this state, pulling the connecting insertion plate 30 may move the snap-fit hook 32 completely out of the snap-fit groove 126, such that the first connection member 10 is separated from the second connection member 20.

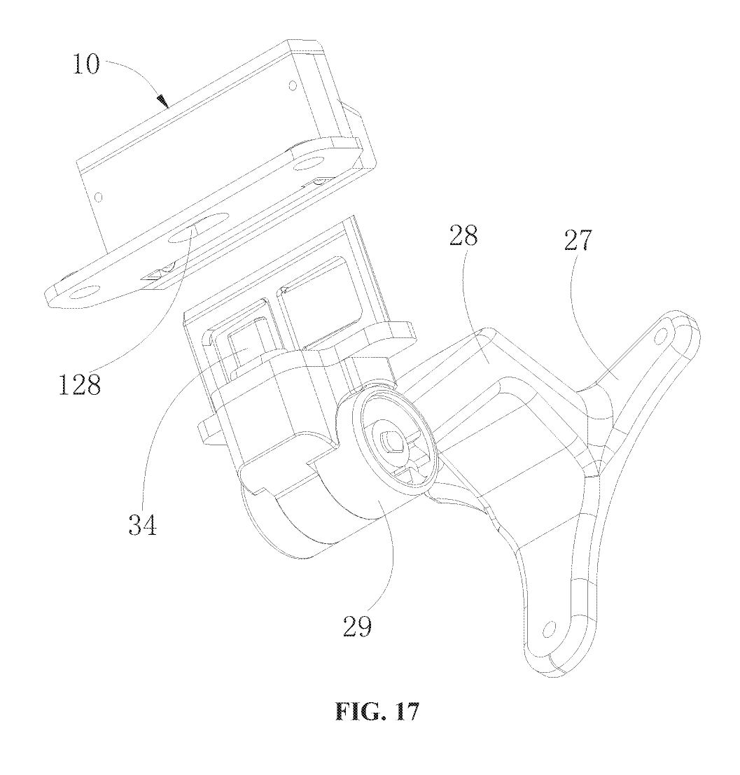

Referring to FIG. 17, the base plate 12 may be provided with a plug hole 128. The second connection member 20 may include a plug 34 disposed at a top surface of the load-bearing member. In some embodiments, the plug 34 may be a USB plug. When the snap-fit hook 32 is coupled with the snap-fit groove 126, the plug 34 may be inserted through the plug hole 128 and connected with the first to-be-connected device 200, thereby realizing the electrical connection between the second connection member 20 and the first to-be-connected device 200. By electrically connecting the second connection member 20 and the second to-be-connected device 300, data transmission may be realized between the first to-be-connected device 200 and the second to-be-connected device 300. When the snap-fit hook 32 is separated from the snap-fit groove 126, the plug 34 may be pulled out from the plug hole 128 to separate the electrical connection between the second connection member 20 and the first to-be-connected device 200.

Referring to FIG. 1 and FIG. 15, an electric device 500 of the present disclosure may include the above-described connection device 100, the display device, and the remote control device. The display device may be connected with the first connection member 10. The remote control device may be connected with the second connection member 20. The display device may be any suitable display devices, such as a cell phone, a tablet, a display screen, etc. The remote control device may be a remote controller.

In the descriptions, terms such as “an embodiment,” “some embodiments,” “example embodiments,” “example,” “illustration,” or “specific example,” or “some examples,” are used to describe that the feature, structure, material, or characteristics may include at least one example or embodiment. In the descriptions, the use of the illustrative expressions does not necessarily indicate that the implementation methods or examples are the same. In addition, the specific feature, structure, material, or characteristics may be combined in any suitable manner in one or more embodiment.

It should be understood that in the present disclosure, the terms such as “first” and “second,” are only used for the purpose of descriptions, and should not be interpreted as indicating or implying any relative importance or explicitly indicating the quantity of the modified technical features. Therefore, a “first” or “second” feature may include, explicitly or implicitly, one or more such features. The term “multiple” means two or more than two, unless otherwise defined.

The above shows and describes various embodiments of the present disclosure. It is understood that these embodiments are illustrative, and should not be construed to limit the scope of the present disclosure. A person having ordinary skills in the art can change, modify, replace, or make variations of the various embodiments within the scope of the present disclosure. Such changes, modifications, replacements, or variations all fall within the scope of the present disclosure.

Other embodiments of the present disclosure will be apparent to those skilled in the art from consideration of the specification and practice of the embodiments disclosed herein. It is intended that the specification and examples be considered as example only and not to limit the scope of the present disclosure, with a true scope and spirit of the invention being indicated by the following claims. Variations or equivalents derived from the disclosed embodiments also fall within the scope of the present disclosure.

What is claimed is:

1. A connection device for connecting a first to-be-connected device and a second to-be-connected device, comprising:
a first connection member configured to connect with the first to-be-connected device, the first connection member comprising a snap-fit groove; and
a second connection member configured to connect with the second to-be-connected device, the second connection member comprising a snap-fit hook configured to couple with the snap-fit groove to limit a relative motion between the first connection member and the second connection member.

2. The connection device of claim 1, wherein the first connection member comprises a base plate configured to fixedly connect with the first to-be-connected device.

3. The connection device of claim 2, wherein the second connection member comprises a movable member, and wherein the snap-fit hook is disposed on the movable member.

4. The connection device of claim 3,
wherein the second connection member comprises a transfer member and a load-bearing member assembled with the transfer member to form a receiving space,
wherein a side wall of the transfer member comprises an opening, and the snap-fit hook is exposed from the opening, and
wherein the movable member is configured to be received in the receiving space and supported by the load-bearing member, and to move within the receiving space to tighten a snap-fitting coupling between the snap-fit hook and the snap-fit groove or to release the snap-fitting coupling.

5. The connection device of claim 4,
wherein the transfer member comprises a top wall and a positioning shaft extending from the top wall toward the movable member, and
wherein the second connection member comprises a transmission assembly supported by the load-bearing member, the transmission assembly configured to drive the movable member to move to tighten the snap-fitting coupling between the snap-fit hook and the snap-fit groove or to release the snap-fitting coupling, the transmission assembly comprising:
a driving rod configured to extend from opening;
a first transmission member connected with the driving rod;
a second transmission member coupled with the first transmission member; and
a cam connected with the second transmission member, the cam and the second transmission member being sleeve-fit onto the positioning shaft.

6. The connection device of claim 5, wherein the first transmission member comprises a first gear, and the second transmission member comprises a second gear.

7. The connection device of claim 6,
wherein the first gear is an internal gear, the driving rod extends from an outer circular circumferential surface of the first gear, and the second gear is an external gear, the second gear extending from an end surface of the cam; or
wherein the first gear is an external gear, the driving rod extends from the outer circular circumferential surface of the first gear, and the second gear is an internal gear, the second gear extending from the end surface of the cam.

8. The connection device of claim 7,
wherein the movable member comprises a first side wall, a second side wall, a third side wall, and a fourth side wall connected in sequence and surrounding the positioning shaft,
wherein the first side wall comprises a through hole corresponding to the opening, and the first side wall extends from the opening,
wherein the second side wall, the third side wall, and the fourth side wall are configured to be received in the receiving space, and
wherein the snap-fit hook is located at a top end of the first side wall.

9. The connection device of claim 8,
wherein the movable member comprises a return column extending from a bottom surface of the movable member toward the load-bearing member, and
wherein the second connection member comprises a return spring received in the receiving space, an end of the return spring configured to abut against the return column, another end of the return spring configured to abut against the load-bearing member.

10. The connection device of claim 7,
wherein the base plate comprises a first wire routing hole, the top wall comprises a second wire routing hole, the positioning shaft comprises a third wire routing hole, and the first wire routing hole, the second wire routing hole, and the third wire routing hole are aligned; or
wherein the base plate comprises the first wire routing hole, the top wall comprises a boss having the second wire routing hole, the positioning shaft comprises the third wire routing hole, the boss is configured to couple with the first wire routing hole, and the first wire routing hole, the second wire routing hole, and the third wire routing hole are aligned; or
wherein the base plate comprises a boss having the first wire routing hole, the top wall comprises the second wire routing hole, the positioning shaft comprises the third wire routing hole, the boss is configured to couple with the second wire routing hole, and the first wire routing hole, the second wire routing hole, and the third wire routing hole are aligned.

11. The connection device of claim 2,
wherein the second connection member comprises a transfer member, the transfer member comprising a top wall, an opening disposed at a side wall, a positioning shaft extending from the top wall toward the movable member, and a blocking plate extending from the side wall of the top wall where the opening is located in a direction away from the positioning shaft.

12. The connection device of claim 11,
wherein the first connection member comprises a side plate extending from a side of the base plate, the side plate comprising a front surface and an opposing back surface, the front surface being closer to the first to-be-connected device than the back surface,
wherein the first connection member also comprises a position limiting member extending from the back surface, and forming a position limiting groove with the back surface, and
wherein the blocking plate is partially or completely received in the position limiting groove.

13. The connection device of claim 2,
wherein the second connection member comprises a load-bearing member and a connecting insertion plate extending from a top surface of the load-bearing member, and
wherein the snap-fit hook is disposed on the connecting insertion plate, and the connecting insertion plate is configured to insert into the snap-fit groove to couple the snap-fit hook with the snap-fit groove.

14. The connection device of claim 13,
wherein the connecting insertion plate comprises a snap-fitting hole, the snap-fitting hole being surrounded by a connection wall, and
wherein the snap-fit hook comprises an elastic plate extending from the connection wall and a snap-fit block provided on the elastic plate, the snap-fit block being configured to swing under an external force and to restore to a natural location after the external force is released.

15. The connection device of claim 14,
wherein the snap-fit block comprises a snap-in segment, a thickness of the snap-in segment configured to gradually reduce in a direction approaching the first connection member, and/or
wherein the snap-fit groove comprises a first wall and a second wall, the first wall disposed closer to the first to-be-connected device than the second wall, and wherein the snap-fit groove comprises a groove formed on the second wall, and the snap-fit block is configured to snap-into the groove to couple the snap-fit hook and the snap-fit groove.

16. The connection device of claim 15,
wherein the first connection member comprises a side plate extending from a side of the base plate, the side plate comprising a front surface and an opposing back surface, the front surface being disposed closer to the first to-be-connected device than the back surface,
wherein the side plate comprises a through hole penetrating through the front surface and connected with the groove, and
wherein the first connection member comprises a pressing member configured to extend into and penetrate through the through hole to extend into the groove to push the snap-fit block to move out of the groove.

17. The connection device of claim 4, wherein a bottom surface of the load-bearing member comprises a rotation arm, and wherein the second connection member comprises:
a base;
a supporting arm extending from the base; and
a connection assembly disposed at an end of the supporting arm away from the base,
wherein the rotation arm is configured to sleeve-fit onto the connection assembly and to rotate to a target location around the connection assembly, and
wherein a pre-tightening force exists between the rotation arm and the connection assembly to maintain the rotation arm at the target location.

18. The connection device of claim 17, wherein the connection assembly comprises:
a first shaft extending from a side of the supporting arm;
a second shaft extending from another side of the supporting arm and being disposed opposite the first shaft and separated from the first shaft;
a first lining block configured to sleeve-fit onto the first shaft; and
a second lining block configured to sleeve-fit onto the second shaft,
wherein the rotation arm is configured to sleeve-fit onto the first lining block and the second lining block, and is located between the first lining block and the second lining block.

19. The connection device of claim 18,
wherein the first shaft comprises a mounting hole, and the second shaft comprises a threaded hole, and
wherein the connection assembly comprises an adjusting member configured to penetrate through the mounting hole to couple with the threaded hole to adjust the pre-tightening force.

20. The connection device of claim 1, wherein the first connection member is configured to connect with a display device, and the second connection member is configured to connect with a remote control device.
